(19) United States
(12) Patent Application Publication
(10) Pub. No.: US 2004/0248419 A1
(43) Pub. Date: Dec. 9, 2004

(54) Method of manufacturing semiconductor device

(75) Inventor: Yoshiharu Ono, Hyogo (JP)

Correspondence Address: McDermott, Will & Emery, 600 13th Street, N.W., Washington, DC, 20005-3096, US

(73) Assignee: RENESAS TECHNOLOGY CORP.

(21) Appl. No.: 10/701,462

(22) Filed: Nov. 6, 2003

(30) Foreign Application Priority Data
Jun. 6, 2003 (JP) 2003-162478(P)

(51) Int. Cl. H01L 21/311

(52) U.S. Cl. 438/694

(57) ABSTRACT

Above a semiconductor substrate are formed a lower conductive layer, an overcoat, a lower insulating film, an etch stop film, and an upper insulating film. A resist pattern formed on the upper insulating film provides holes partially revealing the surface of the overcoat. A wet treatment is performed to the surface of the upper insulating film and the revealed surface within the holes using an acid containing thinner. An organic polymer material film and an organic anti-reflection film are formed to fill the holes. Using a resist pattern formed over the anti-reflection film, an interconnect trench and a hole are formed in the insulating films and other appropriate layers. A plug is formed in the hole and an interconnect is formed in the interconnect trench. This provides a semiconductor device where deterioration of the resolution of a resist is suppressed and non-uniformity of the applied polymer material is prevented.

### BACKGROUND OF THE INVENTION

1. Field of the Invention

The present invention relates to a method for manufacturing a semiconductor device, and more particularly, a method for manufacturing a semiconductor device including the step of forming an interconnect using a dual damascene process.

2. Description of the Background Art

As semiconductor devices become more highly integrated and operate at higher rates in the recent times, it is considered more and more important to reduce the resistance in the interconnection. In order to achieve lower resistivity in the interconnection, a variety of interconnect materials have been examined.

Some interconnect materials are difficult to process using the common dry etching (patterning). In order to overcome such difficulties, a so-called damascene process is proposed in Japanese Patent Laying-Open No. 2001-358216, for example.

In a damascene process, a trench for an interconnect (an interconnect trench), as well as a hole for providing electrical connection between the interconnect and a lower conductive layer are formed in advance in an insulating film and thereafter the interconnect trench and the hole are filled with a conductive material.

A further explanation of the damascene process is provided below. On an insulating film that has been formed to cover the lower conductive layer, a resist pattern that has a hole pattern is formed by a photolithography technique. Using the resist pattern as a mask, the insulating film is then etched to form a hole in the insulating film.

Next, an organic polymer material that serves for anti-reflection is applied to the insulating film to fill the hole. This prevents the lower conductive layer from being damaged during a subsequent etching step to form an interconnect trench.

A resist pattern for an interconnect trench is then formed on the insulating film having the hole. Using the resist pattern as a mask, the insulating film is etched to form in the insulating film an interconnect trench with a predetermined depth. Subsequently, the resist pattern and the organic polymer material are removed.

The interconnect trench and the hole are then filled with a conductive material, forming a plug in the hole and an interconnect in the interconnect trench. The interconnect is electrically connected to the lower conductive layer via the plug. In this way, the interconnect is formed according to the conventional method of manufacturing a semiconductor device.

However, in the conventional method described above, the following problems may be encountered:

There are some materials which may release a basic gas, when used as the insulating film, from their surface appearing on the sidewall of a hole formed in the insulating film. In such a case, when a chemical-amplification resist is employed as a-resist pattern for forming the interconnect trench, an acid component generated in the resist during the exposure process may be neutralized by the basic gas.

The portions of the chemical-amplification resist that are exposed produce acid, which is then used as a catalyst to achieve a reaction for solubilization in the case of a positive-type resist, or insolubilization in the case of a negative-type resist.

Thus, since the acid component that has been generated is neutralized by the basic gas, the reaction for solubilization or insolubilization may be insufficient. The resulting problem is that a resist residue is left, causing the resolution of the resist pattern to deteriorate.

Also, during the application of an organic polymer material to the insulating film to fill the hole, the organic polymer material may not be applied uniformly. The resulting problem is that the hole is not filled sufficiently with the organic polymer material, and thus the lower conductive layer is damaged by the etching step for forming the interconnect trench.

### SUMMARY OF THE INVENTION

The present invention is directed to solving the problems stated above. An object of the present invention is to provide a method of manufacturing a semiconductor device where deterioration of the resolution of a resist is suppressed and non-uniformity of the applied organic polymer material is prevented.

A method of manufacturing a semiconductor device according to the present invention includes the following steps: over the main surface of a semiconductor substrate, a first conductive region is formed; over the first conductive region, an insulating film is formed above the semiconductor substrate; a first recess is formed in the insulating film; the first recess is filled with a filling material; a photoresist is applied to the insulating film; exposure and development are performed to the photoresist to form a resist pattern such that the filling material is revealed; using the resist pattern as a mask, the insulating film is etched to form a second recess which, together with the first recess, defines a recess portion that partially reveals the surface of the first conductive region; the filling material and the resist pattern are removed; the recess portion is filled with a prescribed conductive material to form a second conductive region that is electrically connected to the first conductive region. The method further includes, after forming the first recess in the insulating film, and before filling the first recess with the filling material, performing a wet treatment to the first recess using a resist solvent containing an acid component.

According to the method described above, the wettability of the surface of the insulating film and the revealed surface within the first recess is improved due to the wet treatment performed to the surface of the insulating film and the revealed surface within the first recess using a resist solvent containing an acid component. In this way, during the application of the filling material to the insulating film, non-uniformity of the applied filling material is suppressed, ensuring the first recess to be filled up with the filling material. Further, the wet treatment by an organic solvent containing an acid component adheres the acid component to the surface of the insulating film and the revealed surface within the first recess, neutralizing basic gas generated from the revealed surface within the first recess by virtue of the adhered acid component during the formation of the resist pattern for forming a second recess in the insulating film. As a result, such basic gas does not react with acid generated from the photoresist, and deterioration of the resolution of the resist pattern is thus prevented.

The foregoing and other objects, features, aspects and advantages of the present invention will become more apparent from the following detailed description of the present invention when taken in conjunction with the accompanying drawings.

### BRIEF DESCRIPTION OF THE DRAWINGS

FIG. 1 shows a perspective cross section illustrating a step of a method of manufacturing a semiconductor device according to an embodiment of the present invention.

FIGS. 2-6 are cross sectional views illustrating successive steps performed after the step of FIG. 1 in the present embodiment.

FIG. 7 is a perspective cross section illustrating a step performed after the step of FIG. 6 in the present embodiment.

FIGS. 8 and 9 are cross sectional views illustrating two successive steps performed after the step of FIG. 7 in the present embodiment.

FIG. 10 is a perspective cross section illustrating a step performed after the step of FIG. 9 in the present embodiment.

FIG. 11 is a cross sectional view illustrating a step showing the effect of the method according to the present embodiment.

FIGS. 12-14 are cross sectional views illustrating successive steps performed after the step of FIG. 11 in the present embodiment.

FIG. 15 is a cross sectional view illustrating a step that may be used for a comparison to show the effect of the present embodiment.

FIG. 16 is a perspective cross section illustrating a step of a method of manufacturing a semiconductor device according to a modification of the present embodiment.

FIG. 17 is a cross sectional view illustrating a step showing the effect of a method according to a modification of the present embodiment.

### DESCRIPTION OF THE PREFERRED EMBODIMENTS

A method of manufacturing a semiconductor device using a dual damascene process according to an embodiment of the present invention is described which is exemplified by the case where a hole is first formed in an insulating film and an interconnect trench is formed thereafter.

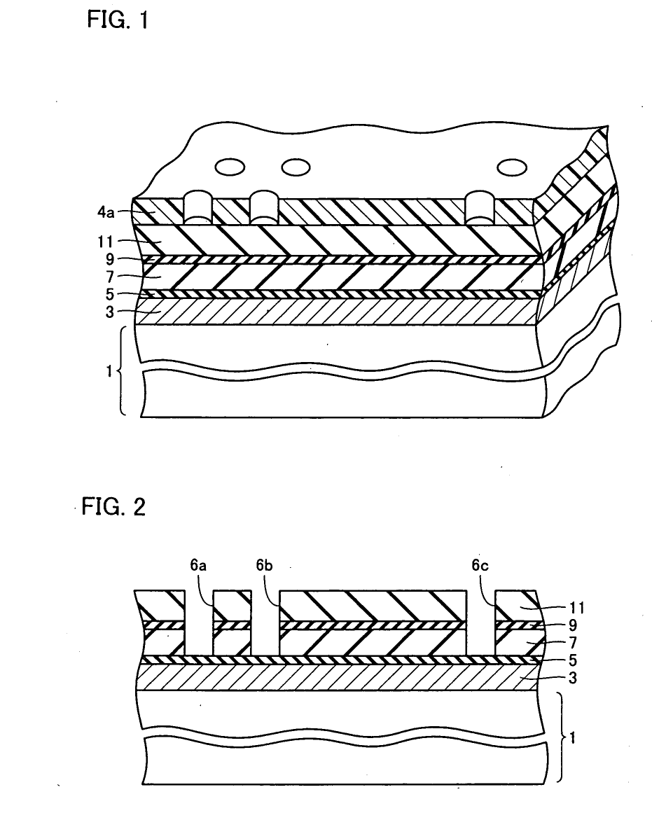

First, as shown in FIG. 1, a lower conductive layer 3 is formed over a semiconductor substrate 1. Over lower conductive layer 3 is formed a prescribed overcoat 5 made of SiN or SiCN, for example. Overcoat 5 serves to prevent lower conductive layer 3 from being damaged during the etching for forming a hole, as described below.

On overcoat 5 is formed an insulating film 7 that is made of SiO, SiOF or SiOC, for example. A prescribed etch stop film 9 made of, for example, SiN is formed on insulating film 7. Etch stop film 9 serves to stop the etching for forming the interconnect trench, as described below.

Further, an insulating film 11 made of SiO, SiOF or SiOC, for example, is formed over etch stop film 9. A resist pattern 4a for forming a hole is formed on insulating film 11.

Insulating film 11, etch stop film 9 and insulating film 7 are anisotropically etched successively with resist pattern 4a as a mask, using a gas such as CF₄ or CHF₃, to form holes 6a-6c, thereby revealing in part the surface of overcoat 5, as shown in FIG. 2.

Next, a prescribed wet treatment is performed to the surface of insulating film 11 and the revealed surface within holes 6a-6c, using a thinner that contains an acid component. A description thereof is provided further below.

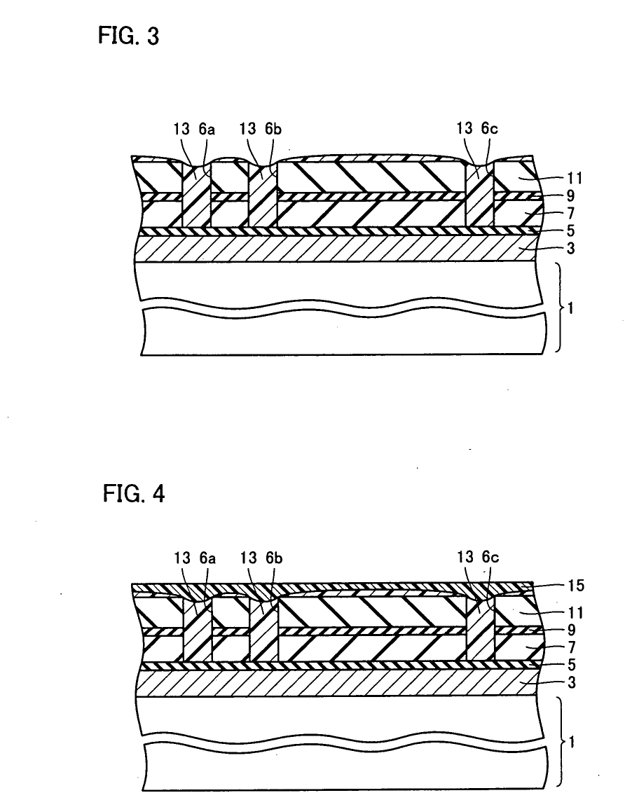

Next, an organic polymer material such as novolac resin is applied to insulating film 11, thereby forming an organic polymer material film 13 (with a thickness of 50 nm-1500 nm) on insulating film 11 for filling holes 6a-6c, as shown in FIG. 3.

Then, as shown in FIG. 4, an organic anti-reflection film 15 (with a thickness of 50 nm-1500 nm) is formed over organic polymer material film 13. Organic anti-reflection film 15 functions later to absorb light that is used for forming a resist pattern, thereby preventing reflection thereof.

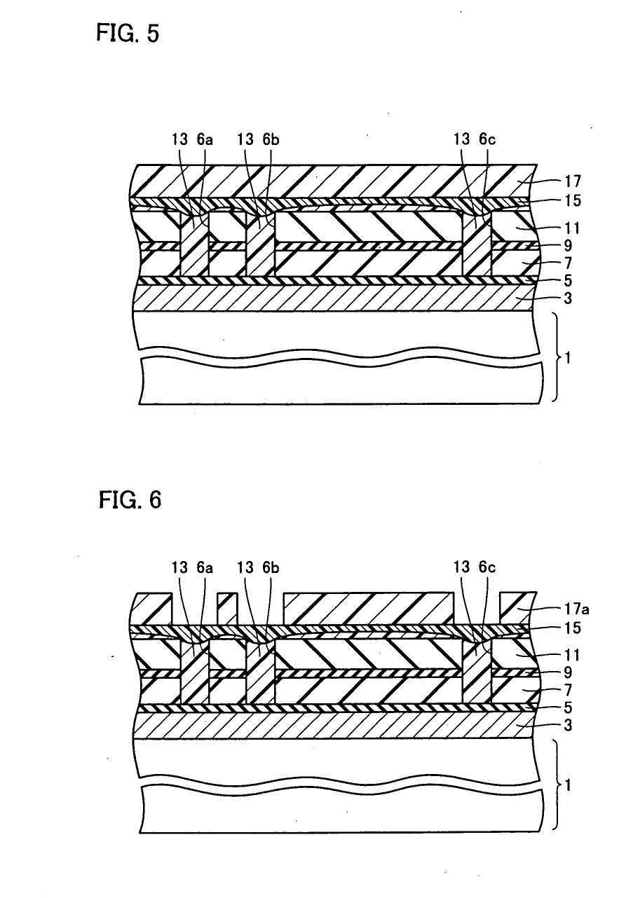

Next, as shown in FIG. 5, a photoresist 17 (with a thickness of 500nm-1500 nm) is applied to organic anti-reflection film 15 using spin coat. The solvent in photoresist 17 is then evaporated by heat treatment (baking) at a temperature of 80-150° C for around 60 seconds, for example.

Next, an exposure process is performed to the photoresist using a source of, for example, ultraviolet light such as the i-line, or far-ultraviolet light of an KrF or ArF excimer laser. After the exposure process, a heat treatment (post-exposure heat process) is performed at a temperature of 80-120° C. for around 60 seconds, for example, to improve the resolution of the photoresist.

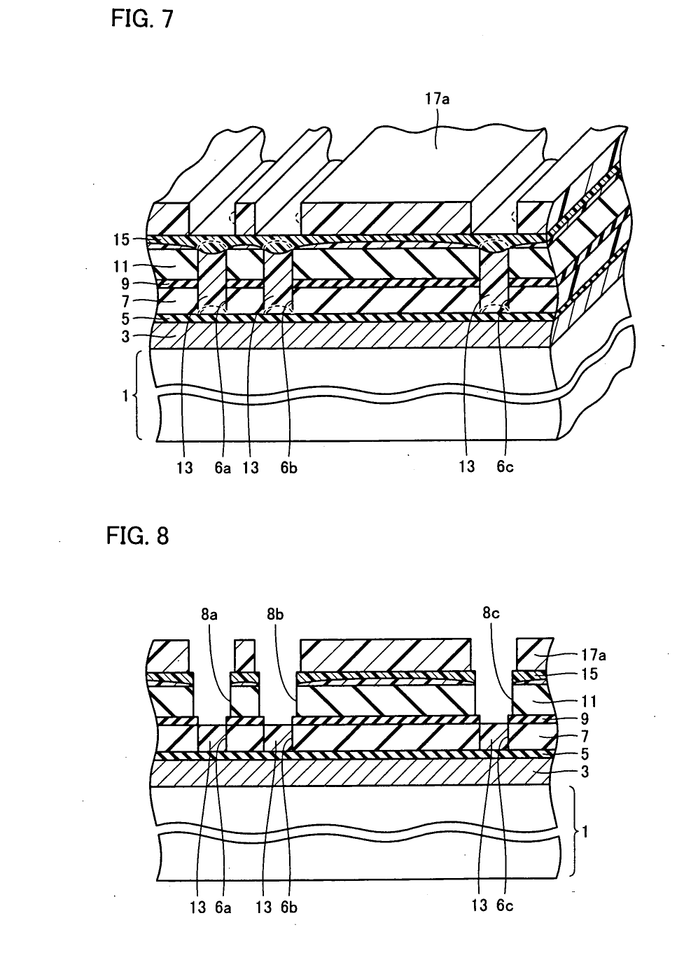

Next, a development process is performed using approximately 2.0-2.5% aqueous alkaline solution of e.g. TMAH (tetramethylammonium hydroxide). Subsequently, a heat treatment is performed, if necessary, at a temperature of 100-130° C. for approximately 60 seconds, for example, to bake the resist pattern. In this way, a resist pattern 17a for forming an interconnect trench is formed, as shown in FIGS. 6 and 7.

Then, as shown in FIG. 8, organic anti-reflection film 15, organic polymer material film 13 and insulating film 11 are anisotropically etched with resist pattern 17a as a mask, partially revealing the surface of etch stop film 9.

Part of organic polymer material film 13 is left in holes 6a-6c. Alternatively, during this etching, organic anti-reflection film 15 and organic polymer material film 13 may first be removed, before insulating film 11 is removed.

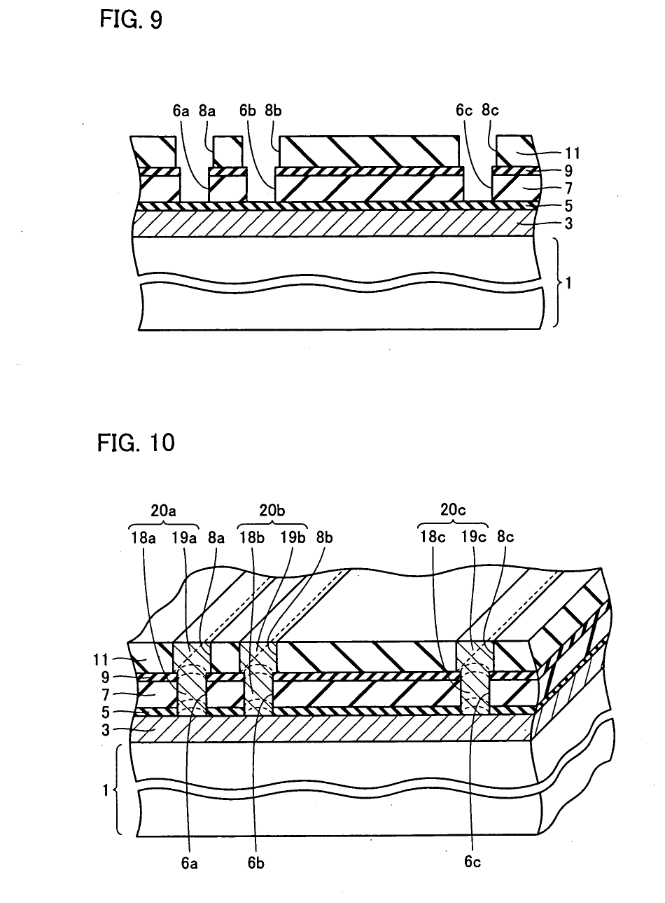

Next, as shown in FIG. 9, resist pattern 17a and organic polymer material film 13 left in holes 6a-6c are removed, partially revealing overcoat 5. The revealed portion of overcoat 5 is then removed, partially revealing the surface of lower conductive layer 3. In this way, interconnect trenches 8a-8c and holes 6a-6c are formed in insulating films 7 and 11, respectively.

A copper film (not shown) is then formed on insulating film 11 to fill up interconnect trenches 8a-8c and holes 6a-6c, using sputtering, for example. Chemical mechanical polishing (CMP) is performed to the copper film thereby removing the copper located on the top surface of insulating film 11. In this way, plugs 18a-18c are formed in holes 6a-6c, while interconnects 19a-19c are formed in interconnect trenches 8a-8c (FIG. 10). This provides upper conductors 20a-20c including plugs 18a-18c and interconnects 19a-19c as in FIG. 10, respectively.

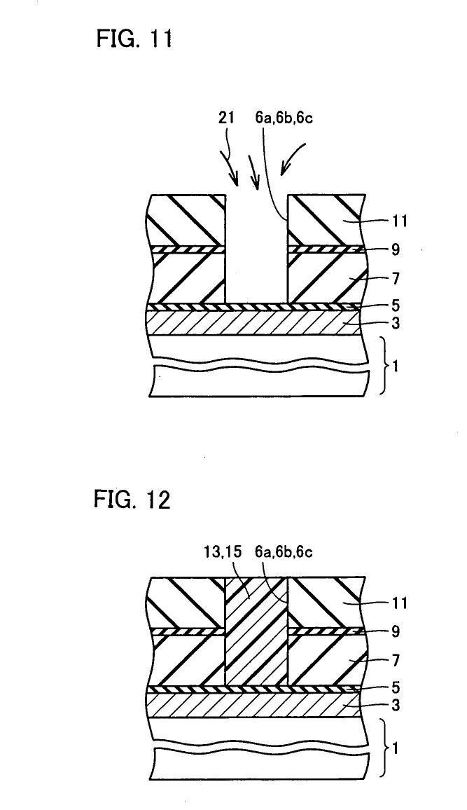

In the method of manufacturing a semiconductor device as described above, a prescribed wet treatment is advantageously performed after the formation of the holes. That is, as shown in FIG. 11, a wet treatment is performed after the formation of holes 6a-6c to the surface of insulating film 11 and the revealed surface within holes 6a-6c using a thinner 21 containing an acid component.

Thus, the wettability of the surface of insulating film 11 and the revealed surface within holes 6a-6c is enhanced, and non-uniformity of organic polymer material applied to insulating film 11 is suppressed. As a result, holes 6a-6c can be filled sufficiently with organic polymer material to form organic polymer material film 13 as in FIG. 12.

Moreover, the wet treatment prevents deterioration of the resolution of the resist pattern caused by the loss of effect of the acid generated in chemical-amplification photoresist 17 due to a basic gas. This will be discussed below.

First, a chemical-amplification photoresist 17 is used as a resist pattern for forming an interconnect trench, as described above. When using chemical-amplification photoresist 17, acid is produced in its exposed portions.

At this time, a prescribed reaction that causes the photoresist to be dissolved in a developer with the generated acid as a catalyst (solubilization reaction) occurs in the case of a positive-type photoresist, while, for a negative-type photoresist, a prescribed reaction occurs that prevents the photoresist to be dissolved in a developer with the generated acid as a catalyst (insolubilization reaction).

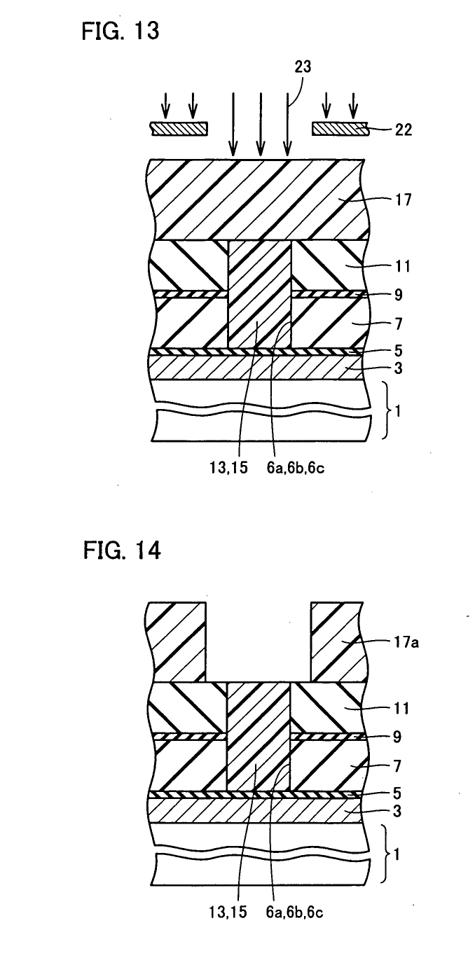

By performing a wet treatment by thinner 21 containing an acid component, the acid component adheres to the surface of insulating film 11 and the revealed surface within holes 6a-6c. Then, as shown in FIG. 13, when light 23 is directed through mask 22 to form a resist pattern for forming an interconnect trench in insulating film 11, the basic gas generated from the surface of holes 6a-6c is neutralized by the adhered acid component.

Therefore, such basic gas does not react with acid generated in chemical-amplification photoresist 17, ensuring a prescribed solubilization or insolubilization reaction in the photoresist to be performed reliably. As a result, deterioration of the resolution of the resist pattern is prevented, allowing a desired resist pattern 17a to be well formed, as shown in FIG. 14.

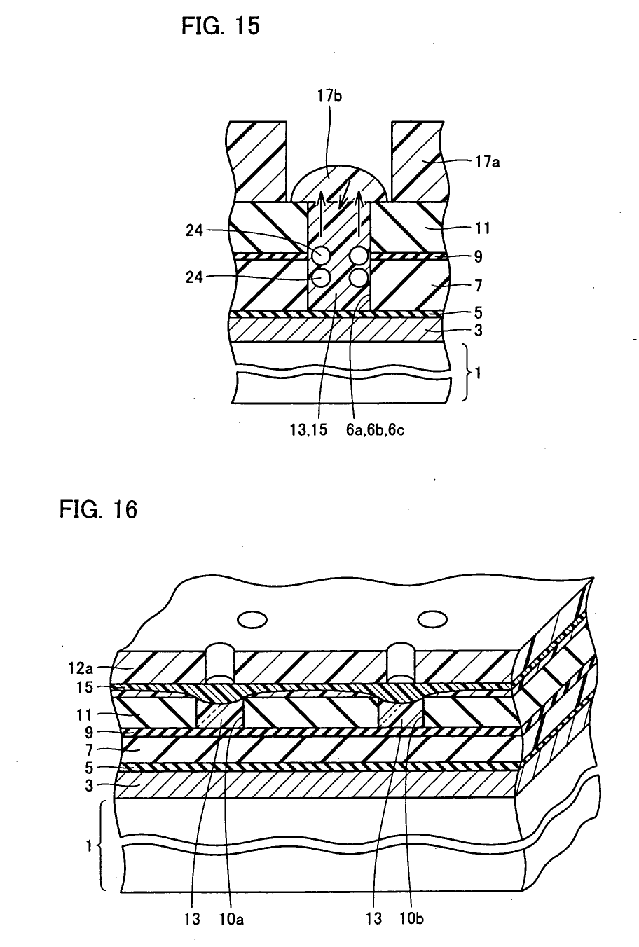

On the other hand, using the conventional method as in FIG. 15, during the formation of a resist pattern for forming an interconnect trench in insulating film 11, a component in the basic gas 24 generated from the surface of holes 6a-6c reacts with acid generated in the photoresist during the exposure process, resulting in a loss of effect of the acid in the photoresist.

Consequently, a prescribed solubilization or insolubilization reaction in the photoresist is not satisfactory. This in turn results in inferior resolution of resist pattern 17a due to a resist residue 17b, impeding the formation of a desired interconnect trench.

Supposedly, a basic gas is generated because a gas such as NH₃, N₂ and the like used for forming insulating films 7, 11 remain in the insulating film, and a component of the remaining gas in a region of the surface of e.g. insulating films 7, 11 revealed at the side of holes 6a-6c is emitted due to the heat treatment for forming the resist pattern.

Particularly, when an SiOC-based amorphous insulator having a relatively low permittivity is used for insulating films 7, 11, then the film itself has a relatively small density and hence a permeability for gas higher than the normal silicon dioxide (SiO₂). Thus, deterioration of the resolution of a resist pattern tends to be more significant.

Accordingly, the method described above is advantageously used when a chemical-amplification photoresist is employed and an amorphous silicon insulator is used for the insulating film, preventing deterioration of the resolution of a resist pattern effectively.

For a thinner containing an acid component used for the wet treatment, it is desirable to employ a thinner that is used as a solvent for the resist.

Also, the wet treatment described above may alternatively be performed after organic polymer material film 13 has been formed and prior to the formation of organic anti-reflection film 15. In this case, organic anti-reflection film 15 can be formed uniformly.

Furthermore, the wet treatment may be performed after organic anti-reflection film 15 has been formed and prior to the application of photoresist 17 for forming an interconnect trench. In this case, photoresist 17 can be applied uniformly.

Moreover, although the method described above is exemplified by the case where interconnect trenches 8a-8c are formed after the formation of holes 6a-6c, it can also be used when the holes are formed after the formation of interconnect trenches.

In this case, a resist pattern (not shown) for forming interconnect trenches are formed over insulating film 11 and, using the resist pattern as a mask, anisotropic etching is performed to insulating film 11, providing interconnect trenches 10a, 10b as in FIG. 16.

Next, as described above, a wet treatment is performed using a thinner containing an acid component. Then, organic polymer material film 13 and organic anti-reflection film 15 are formed to fill interconnect trenches 10a, 10b.

A resist pattern 12a for forming a hole in insulating film 11 and other appropriate layers is then formed over organic anti-reflection film 15. Organic polymer material film 13, organic anti-reflection film 15 and insulating film 7 and other appropriate layers are anisotropically etched with resist pattern 12a as a mask, thereby providing a hole (not shown).

Subsequently, as in the method described above, a copper film is formed and chemical mechanical polishing (CMP) is performed thereto, forming upper conductors 20a-20c including plugs 18a-18c and interconnects 19a-19c as in FIG. 10, respectively.

The wettability is also improved in this method due to the wet treatment to the surface of insulating film 11 and the revealed surface within interconnect trenches 10a, 10b using a thinner containing an acid component.

This can prevent, non-uniform application of organic polymer material, ensuring interconnect trenches 10a, 10b to be filled up with organic polymer material to form organic polymer material film 13, as shown in FIG. 16.

Further, the wet treatment by a thinner containing an acid component adheres the acid component to the surface of insulating film 11 and the revealed surface within interconnect trenches 10a, 10b, thereby neutralizing basic gas from the surface of interconnect trenches 10a, 10b during the formation of resist pattern 12a for forming a hole in insulating film 11.

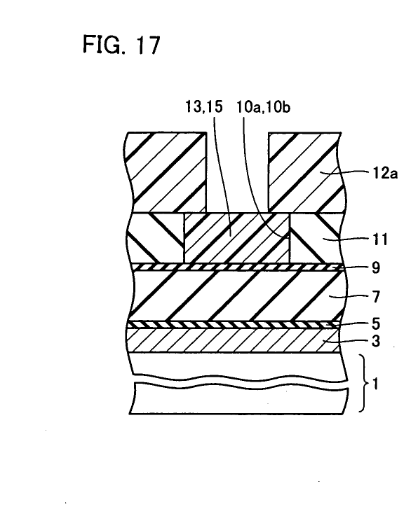

Consequently, such basic gas does not react with acid generated in the chemical-amplification photoresist, preventing the resolution of the resist pattern from deteriorating. As a result, a desired resist pattern 12a is reliably formed as in FIG. 17.

Although the present invention has been described and illustrated in detail, it is clearly understood that the same is by way of illustration and example only and is not to be taken by way of limitation, the spirit and scope of the present invention being limited only by the terms of the appended claims.

What is claimed is:

1. A method for manufacturing a semiconductor device comprising the steps of:
forming a first conductive region on a main surface of a semiconductor substrate;
forming an insulating film above said semiconductor substrate to cover said first conductive region;
forming a first recess in said insulating film;
filling said first recess with a filling material;
applying a photoresist to said insulating film;
by performing exposure and development to said photoresist, forming a resist pattern such that said filling material is revealed;
by etching said insulating film with said resist pattern as a mask to form a second recess, forming a recess portion defined by said first recess and said second recess revealing a surface of said first conductive region;,
removing said filling material with a prescribed conductive material and said resist pattern; and
by filling up said recess portion, forming a second conductive region electrically connected to said first conductive region,
said method including the step of performing a wet treatment to said first recess by a resist solvent containing an acid component after forming the first recess in said insulating film and before filling said first recess with the filling material.

2. The method according to claim 1, wherein said step of forming the first recess includes forming a hole as the first recess, and
said step of forming the second recess includes forming an interconnect trench as the second recess.

3. The method according to claim 2, further comprising, before said step of forming the insulating film, the step of forming another insulating film having a different etching property from said insulating film above the main surface of said semiconductor substrate,
said step of forming the first recess including the step of revealing a surface of said another insulating film at a bottom of said first recess, and
said step of forming the second recess including the step of removing said revealed another insulating film.

4. The method according to claim 2, wherein said step of forming the insulating film includes the steps of
forming a first layer having a prescribed etching property, and
forming over said first layer a second layer having a different etching property from said first layer,
said interconnect trench being formed in said second layer.

5. The method according to claim 1, wherein said step of forming the first recess includes forming an interconnect trench as the first recess, and
said step of forming the second recess includes forming a hole as the trench.

6. The method according to claim 5, wherein said step of forming the insulating film includes the steps of
forming a first layer having a prescribed etching property, and
forming over said first layer a second layer having a different etching property from said first layer,
said interconnect trench being formed in said second layer.

7. The method according to claim 1, wherein said insulating film includes an amorphous silicon-based insulating film, and said photoresist includes a chemical-amplification photoresist.
